(19) United States
(12) Patent Application Publication
(10) Pub. No.: US 2023/0252204 A1
(43) Pub. Date: Aug. 10, 2023

(54) METHOD FOR GENERATING A VIRTUAL MODEL OF A COMPONENT, COMPUTER SYSTEM, AND COMPUTER PROGRAM PRODUCT

(71) Applicant: Siemens Industry Software NV, Leuven (BE)

(72) Inventors: Kai Liu, Heroldsberg (DE); Dorlis Bergmann, Rückersdorf (DE); Andreas von Schwerin, München (DE)

(21) Appl. No.: 18/106,998

(22) Filed: Feb. 7, 2023

(30) Foreign Application Priority Data
Feb. 8, 2022 (EP) 22155614.5

(51) Int. Cl. G06F 30/20

(52) U.S. Cl. CPC G06F 30/20

(57) ABSTRACT

A method for generating a virtual model of a component using a computer-aided design (CAD) environment including a design database is provided. The design database is used to store designs. The CAD environment provides predefined design elements. At least some of the designs include predefined design elements. In order to increase an efficiency with which models are created, a design databank contains information from the design database relating to designs. In a design phase, the method further includes selecting at least one design element, determining designs that contain the selected design element from the design databank, and displaying information relating to at least one of the determined designs.

This application claims the benefit of European Patent Application No. EP 22155614.5, filed Feb. 8, 2022, which is hereby incorporated by reference in its entirety.

### BACKGROUND

The present embodiments relate to a method for generating a virtual model of a component using a computer-aided design environment including a design database.

Such a computer-aided design environment is, for example, the commercial simulation software Simcenter Amesim. This is used to model and analyze multi-domain systems. Simcenter Amesim includes a number of tools that are used to model, analyze, and predict the performance of mechatronic systems. The models are described using non-linear, time-dependent analytical equations that represent the hydraulic, pneumatic, thermal, electrical, or mechanical behavior of the system. In contrast to 3D CAE modeling, this approach makes it possible to simulate the behavior of systems before a detailed CAD geometry is available, and is therefore used at an earlier time in the system design cycle or V-model.

The creation of a model in a computer-aided design environment, such as Simcenter Amesim, or computer-aided design software, such as Simcenter NX, for an application with a number of complex design elements requires a considerable amount of effort by the engineer to select the correct design elements or models from the library and to define parameters for these design elements. This is arduous and even error-prone for a beginner or occasional user of the software application.

Comprehensive training of inexperienced users and support from experts were previously needed to deal with such computer-aided design environments.

A complicated study of existing designs, library documentation, and user handbooks is usually needed to find a suitable design element for the intended purpose.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a method of the type defined at the outset such that the problems and disadvantages explained are avoided is provided.

In detail, the method defined at the outset is developed, according to the present embodiments, by providing for a design databank to contain information from the design database relating to designs. Further, further acts are provided in a design phase: (b1) selecting at least one design element; (b2) determining designs that contain the selected design element, from the design databank; and (b3) displaying information relating to at least one of the determined designs.

Specific meanings of the terms that are useful for better understanding of the invention are explained below.

The term “component” should be understood in the broadest sense and, for example, may be considered to be a complex assembly or a complete product consisting of a plurality of individual parts. Examples are complete automobiles, ships, aircraft, or assemblies or components thereof.

Computer-aided design is the use of computers or workstations to assist with creating, changing, analyzing, or optimizing a design. CAD software is used to increase the productivity of the designer, to improve the quality of the design, to improve communication using documentation and to create a database for manufacturing. CAD is often understood in the narrower sense and provides only the computer-aided creation and modification of the geometric model. The present embodiments use a broader understanding of CAD. CAD may be all computer-aided activities in a design process, including geometric modeling, calculation, simulation, and other information capture and provision, from the development of the concept to the transfer to production or manufacturing.

In the wording of the present embodiments, data from a design database may include images, knowledge, existing designs, user handbooks, documentation, or additional information.

In the case of a graph database, the data is created in a network structure, where graphs are used to represent and store hierarchical and/or networked information. Such a graph consists of nodes and directed or undirected edges. The edges are connections between the nodes. Known concepts for graph databases are the resource description framework and labeled-property graph.

A knowledge graph is a graph database in which “knowledge” is stored. On account of the vague term of “knowledge”, this term is not unambiguously differentiated from other graph databases.

A knowledge graph generally has these features: elements are semantically described; and a meaning may be ascribed to the data using an ontology.

A data collection phase may be upstream of the design phase, but may also take place in a parallel manner and/or alternately with one another, with the result that the design database may be supplemented with further designs.

Design elements are technical modules that may be in the form of physical substitute models. In the computer-aided design environment, these design elements are made available to the user as functions, programs, modules, or objects in order to possibly combine the design elements with one another and to represent more complex systems and processes in this manner. These design elements may generally be parameterized and may generate at least one output from at least one input.

Determining the design elements contained in a design may provide, for example, that the type of elements and, for example, also any parameterization of the design element are determined. Arranging the determined design elements in a design may include arranging the individual elements with respect to one another and functionally linking the individual elements to one another. For example, the individual elements may also be arranged or positioned in a respective image or the image file of a design, for example, such that it is possible for a user to interact with this image on a screen using a cursor, with the result that information relating to the specific design elements represented is displayed.

Designs created using the computer-aided design environment generally contain at least some predefined design elements or at least one predefined design element that is made available to the user by a design element collection in the computer-aided design environment.

A design database serves the users of the computer-aided design environment to save, store or buffer started or completed designs. These designs are generally available to a plurality of users at least with read rights.

A database that is in the form of a graph database (e.g., a knowledge graph) provides for the individual elements or entities to generally not be saved in any desired format, but rather, requires the compliance with predefined formatting conditions. For graphical elements, this may be conversion into a string (e.g., serialization into string).

The design databank according to the present embodiments may be in the form of a graph database (e.g., in the form of a knowledge graph design collection).

In the present case, unless stated otherwise, information is displayed by a display unit (e.g., by a screen, a monitor, or an optical display unit).

At the start or over the course of the method according to the present embodiments, the user has the option of determining predetermined criteria for the work in order to make assistance by the method particularly efficient. These may include group criteria for, for example, a subgroup of the determined designs (e.g., by inputting a group affiliation of the design to a technology group, such as automobile, marine, wind power, energy generation or pneumatics, hydraulics, electrics).

These predetermined criteria also make it possible to provide context-sensitive widgets via a man-machine interface (e.g., in order to enable user interactions).

The provision of context-sensitive widgets in the preview enables user interactions via these widgets.

These widgets may be displayed by a display device such as a monitor, a VR device, or another suitable display device.

Data may be extracted from the design database, which may also be referred to as a design collection, by a design extractor module. The design collection serves the engineer as a memory for the designs in daily work.

Context-based information in an enhanced preview image may be provided by a design assistance module.

According to one development, the recommended use may be determined by an artificial intelligence module that takes into account the frequency of previous designs or of the determined designs and/or their similarity to the design in the design phase, or receives the recommended use as an input. In this case, the degree of similarity may be due, for example, to a similarity of the technological field of the design project to those of the determined designs and/or to the number of design elements used and/or an order of magnitude of physical parameters. The artificial intelligence for determining a suitable recommended use for the user may be trained using a user behavior (e.g., across a plurality of users; across a plurality of entities of the computer-aided design environment) in any case according to the present embodiments by accessing information from the design database that is contained in the design databank.

One development of the present embodiments provides, for the method, in a (a) data collection phase, to include the further acts of: (a1) selecting a design from the design database; (a2) extracting data from the selected design; (a3) converting the data into a graph database format; and (a4) storing the converted data in a design databank, where the design databank is in the form of a graph database.

When selecting the design, a selection module may use predetermined criteria that prioritize the collection of data. Alternatively, the designs may be processed in a sorted order.

One development of the present embodiments may provide for act (a2) to include: creating an image file of the design selected in act (a1); and determining the design elements contained in the design and an arrangement of the design elements in the image in the image file.

The image file may be created as a simple pixel file (e.g., PNG, JPG), for example, as an export or photograph. The individual design elements may be recognized based on characteristic symbolism of the individual design elements, and the arrangement and an areal extent of the individual design elements may then be assigned as additional information to the image file.

A further development of the present embodiments provides for act (a2) to include serializing the image file into a string image file.

This format conversion makes it possible to save this data in a graph database (e.g., in the form of a knowledge graph).

A design databank contains information from the design database relating to designs. In a design phase (b), the method includes further acts of: (b1) selecting at least one design element; (b2) determining designs that contain the selected design element from the design databank; and (b3) displaying information relating to at least one of the determined designs.

One development of the present embodiments provide for act (b3) to include:

(b31) determining information relating to design elements that are arranged adjacent to the design element selected in act (b1) in the designs determined in act (b2); and (b32) displaying the information that is determined in act (b31) and relates to at least one design element.

These suggestions of preferred adjacent components are time-saving for the user (e.g., for the inexperienced user) because the search for an appropriate design element in the multiplicity of design elements provided by the design element collection is particularly time-consuming.

One development of the present embodiments provides, for the information relating to use of the adjacently arranged design element as a design element adjacent to the selected design element, for statistics or a frequency in the determined designs or in a subgroup of the determined designs to be determined and displayed.

In a fundamental analysis, a large number of design elements in different designs may occur with the same neighbors. Therefore, it is useful for a user to receive indications of the frequency with which corresponding adjacent design elements are used for the current design element, with the result that this indication accordingly often leads to the desired time saving.

One development of the present embodiments provides, for the information relating to use of the adjacently arranged design element as a design element adjacent to the selected design element, for a recommended use as a design element adjacent to the selected design element to be determined and displayed. A recommended use may be displayed to the user by a corresponding agent or a recommendation module (e.g., design recommender). In this case, the recommendation module may be a trained AI module that permanently learns from the user behavior and/or by analyzing existing designs from the design databank and/or the design database for the purpose of improving the recommendation algorithm.

One development of the present embodiments provides for at least one predetermined group criterion to define the subgroup of the determined designs.

One development of the present embodiments provides for the user to be provided with one of the following options: to adopt at least one adjacent design element; or to adopt at least one adjacent design element and further design elements adjacent to the adjacent design element from the determined designs of adjacent design elements for arrangement in the design in the design phase. Both the individual adoption and the adoption of a plurality of elements or entire residual designs may save the user time (e.g., if the design in the design phase strongly resembles an already existing design).

One development of the present embodiments provides for the virtual model to be a simulation model for simulating use of the component using at least one computer. In this case, the use of the component may relate to individual parts of a technical system or to complete technical products in an environment corresponding to the typical operating environment.

One development of the present embodiments provides for the user to be able to automatically or manually prompt a query in the design databank in the design phase for a particular design element. The query is used to investigate the use of the design element in earlier designs. For this purpose, the design environment may contain a design element detector module that automatically retrieves designs from the design databank using the design element of the same type from the design databank.

One development of the present embodiments provides for the selection of an offered design with a design element to cause the generation of a preview (e.g., using a preview generator of the design environment). The preview generator may carry out at least some (e.g., all) of the following acts: de-serializing the string image file of the selected design into an image file; retrieving geometric properties (e.g., coordinates, width and height) of the entities of the at least one design element that is offered for adoption in the present design; adapting the geometry of the design element offered for adoption to the representation of the design that has used the proposed design element (e.g., adapting aspect ratios and/or scaling); creating an image overlay for superimposing the design element offered for adoption in a representation of the design that has used the proposed design element and, for example, providing additional information relating to the proposed design element (e.g., parameters, behavior models, documentation); combining the image overlay with the representation of the design that has used the proposed design element (e.g., in order to create a preview image enhanced with additional functions and/or information); and generating context-sensitive widgets in the enhanced preview image (e.g., in order to enable user interactions).

In one embodiment, a design element in the preview image is selected (e.g., instantiated), and at least one design element parameter is defined.

One development of the present embodiments provides for a method according to the present embodiments to be carried out, where the method is part of a method for improving or optimizing the component. In detail, the improvement or optimization process may include the following acts that may be repeated, with the result that there is an iteration: defining an improvement goal/optimization goal; providing a starting specification for the component; specifying changes to the component, thus resulting in a plurality of changed component specifications; generating the models or simulation models in accordance with the method of the present embodiments for generating a virtual model for each component specification; simulating the operation of the various components; determining when the improvement goal/optimization goal is approximated for each individual component; and determining the component specification that provided the best approximation as the new starting specification or as the result of the method for improving or optimizing components.

A further development of the present embodiments provides for a method of the present embodiments to be carried out, where the method is part of a production method that provides for the component that is to be produced to be verified, improved, or optimized before the component is produced by a manufacturing process. In this case, the manufacturing process may be an additive manufacturing process or may include additive manufacturing acts. The manufacturing process may also include assembling a plurality of possibly different components that have been tested, verified, improved, or optimized individually or in combination with one another in terms of their suitability and their advantages and disadvantages during operation using a simulation using models that have been generated using the method according to the present embodiments.

### BRIEF DESCRIPTION OF THE DRAWINGS

FIG. 1 shows a schematic, simplified illustration of a sequence of a method according to an embodiment, a corresponding computer system for carrying out the method, and a computer program product including the method; and

FIGS. 2 and 3 each show an exemplary illustration of an operating and information interface of a design environment on a screen while carrying out the method.

### DETAILED DESCRIPTION

Functionally same components may be provided with same reference signs. Functionally same components may not be identified in all figures and are also not explained separately again for each individual figure. It may be assumed that these components in the different illustrations each have a substantially same function.

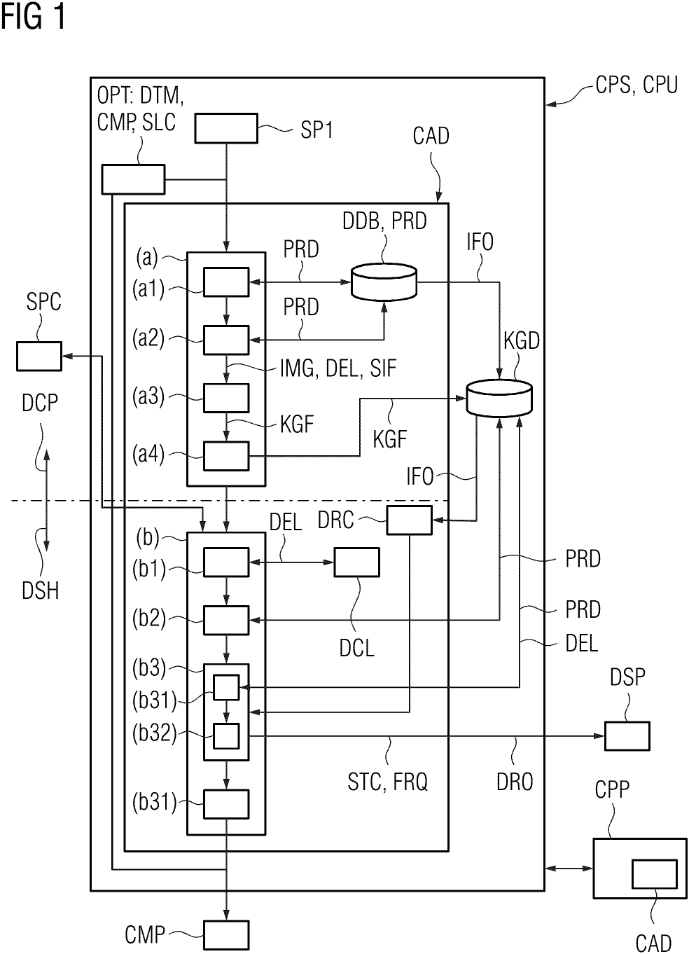

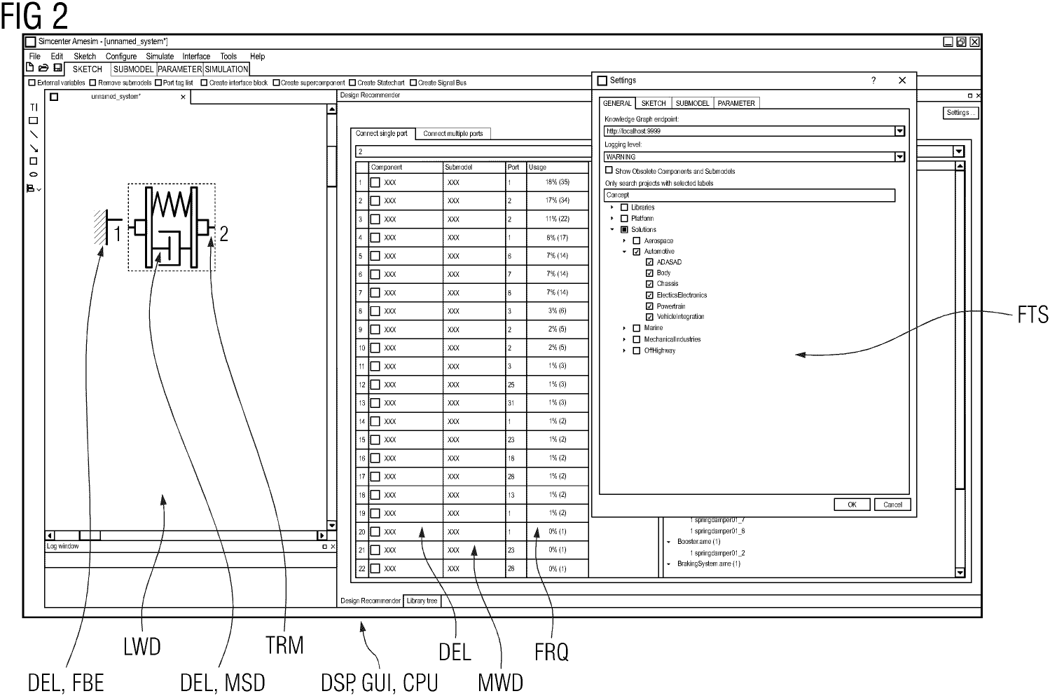

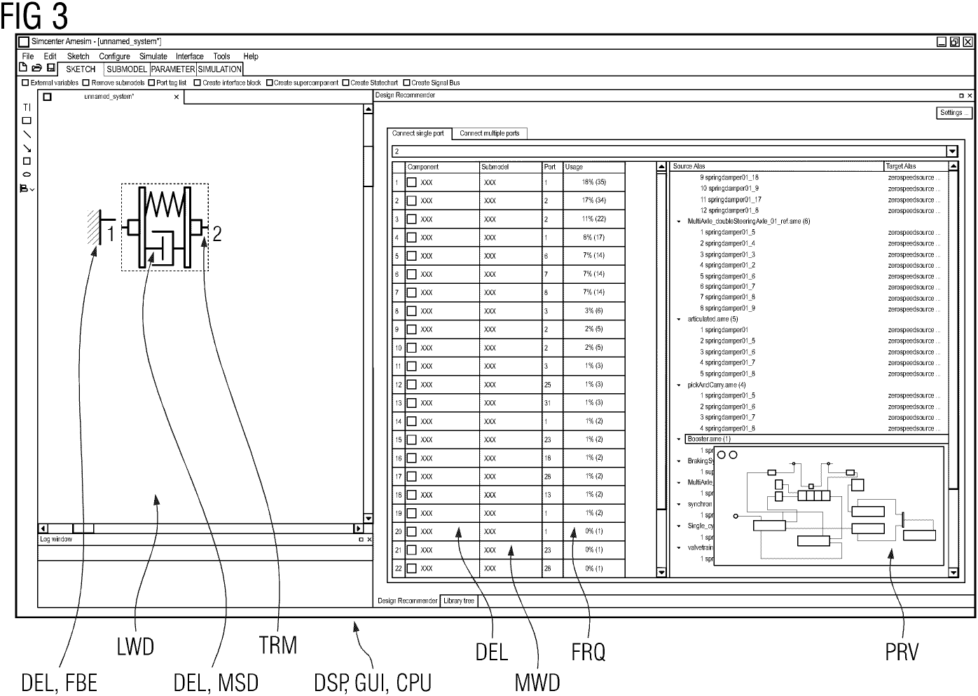

FIG. 1 shows a schematic, simplified illustration of a sequence of one embodiment of a method, a corresponding computer system CPS for carrying out the method, and a computer program product CPP including the method. FIGS. 2-3 show, by way of example, a user interface GUI displayed on a screen DSP in exemplary situations while carrying out the method.

The method illustrated in FIG. 1 is used to generate a virtual model MDL of a component CMP using a computer-aided design environment CAD including a design database DDB. This virtual model MDL is a simulation model for simulating use of the component CMP by at least one computer CPU. The design database DDB is used to store designs DSG. The design database DDB provides predefined design elements DEL from a design element collection DCL for the design environment CAD. At least some of the designs DSG include predefined design elements DEL (e.g., all designs DSG include a plurality of predefined design elements DEL).

In addition to the design database DDB, a design databank KGD is provided, according to the present embodiments, in the design environment CAD and contains information IFO from the design database DDB relating to designs PRD. The design databank KGD is in the form of a graph database.

In a data collection phase DCP (a), the method includes the following acts of: (a1) selecting a design PRD from the design database DDB; (a2) extracting data from the selected design PRD; (a3) converting this data into a graph database format KGF; and (a4) storing this converted data in a design databank KGD.

Further, act a2 includes the following intermediate acts: creating an image file IMG of the design PRD selected in act a1; determining the design elements DEL contained in this design PRD and an arrangement of the determined design elements DEL in the image in the image file IMG; and serializing the image file IMG into a string image file SIF.

In a design phase DSH (b), the method includes the further acts of: (b1) selecting at least one design element DEL; (b2) determining designs PRD that contain the selected design element DEL from the design databank KGD; and (b3) displaying information relating to at least one of the determined designs PRD using a screen DSP.

In this case, act (b3) is subdivided into further intermediate acts of: (b31) determining information relating to design elements DEL that are arranged adjacent to the design element DEL selected in act b1 in the designs PRD determined in act b2; and (b32) displaying the information that is determined in act b31 and relates to at least one design element DEL.

It is easier for the user to select a design element adjacent to the current design element by virtue of the fact that, for the information relating to use of the adjacently arranged design element DEL as a design element DEL adjacent to the selected design element DEL, statistics or a frequency in the determined designs PRD or in a subgroup of the determined designs PRD is/are determined and displayed. For this purpose, a recommended use DRO as a design element DEL adjacent to the selected design element DEL may be determined and displayed. At least one predetermined group criterion may be provided for defining a subgroup of the determined designs. This group criterion may be defined, for example, by the user for a project or for individual components. This may be, for example, a field of use for this component or a technological field or a particular production method or a combination of these criteria. For example, the technological field may be defined as an automobile, with the result that design elements that have likewise been used for automobile-related projects in a corresponding design context (e.g., adjacent design element(s)) may be offered to the user for the recommended use, for example. These design elements DEL (e.g., at least one adjacent design element DEL or at least one adjacent design element DEL and further design elements DEL adjacent to the adjacent design element DEL) are offered to the user for adoption in his own design, with the result that the user may adopt these adjacent design elements DEL from the determined designs for arrangement in the design DSG in the design phase DSH.

The computer CPU that is used to operate the design environment CAD may be in the form of a computer system CPS including at least one computer CPU prepared to execute the design environment CAD. This computer system CPS may be in the form of a network having a plurality of computers CPU, with the result that data may be interchanged between the individual computers CPU, and there is joint access to the design database DDB and the design databank KGD.

FIGS. 2, 3 each show a graphical user interface GUI of the design environment CAD in different operating situations.

In FIGS. 2, 3, a design element DEL is in the form of a mass-spring-damper system MSD in a left-hand window LWD. A further design element DEL is arranged as a fixed bearing FBE to the left of and adjacent to the design element DEL.

Potentially suitable design elements DEL for adjacent arrangement are proposed to the user for a second connection end point TRM on the screen DSP, in a second window MWD arranged approximately centrally, seen from the left, illustrated in FIG. 2. In the specific operating situation, the user has selected the first design element DEL offered, and properties FTS of this design element DEL are displayed. The design elements DEL offered are organized and numbered in an order. This order depends on, for example, the frequency FRQ of the arrangement of these design elements DEL organized in the order in terms of use in a comparable design from the design databank KGD as an adjacent design element DEL.

The illustration in FIG. 3 shows a preview PRV or an image of a design PRD that comes from the design databank KGD and contains the arrangement of the design element DEL, as in the design in the design phase DSH, with an adjacent design element DEL according to the selected proposal (e.g., the proposal with priority 1). In this manner, the user may envision the technical context in which the proposed combination of design elements DEL has already been used in a design.

In the present case, the present embodiments are described with respect to the claimed method. Features, advantages, or alternative embodiments herein may be assigned to the other claimed subjects (e.g., the computer program or an apparatus, such as the apparatus or a computer program product), and vice versa. In other words, the subject matter claimed or described with respect to the apparatus may be improved with features that are described or claimed in connection with the method, and vice versa. In this case, the functional features of the method are embodied by structural units of the system, or vice versa. In information technology, a software implementation and a corresponding hardware implementation are generally equivalent. For example, a method step for “storing” data may be carried out using a memory unit and corresponding instructions for writing data to the memory. In order to avoid redundancy, the apparatus may also be used in the alternative embodiments described with reference to the method, but these embodiments are not explicitly described again for the apparatus.

The present embodiments include the fact that not all acts of the method have to be necessarily carried out on the same computer identity, but rather, may also be carried out on different computer entities. A network of computers may be used for this purpose.

In this case, it is possible, for example, for individual acts of the method described above to be able to be carried out in one unit, and for the remaining acts to be able to be carried out in another unit as a distributed system.

The above-described properties, features, and advantages of the present embodiments and the manner in which they are achieved become clearer and more comprehensible in the light of the following description and embodiments, which are described in more detail in the context of the drawings.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for generating a virtual model of a component using a computer-aided design (CAD) environment comprising a design database, the method comprising:
storing, using the design database, designs;
providing, by the CAD environment, predefined design elements from a design element collection, wherein at least some of the designs comprise predefined design elements, and wherein a design databank contains information from the design database relating to the designs; and
in a design phase:
selecting at least one design element of the predefined design elements,
determining designs that contain the at least one selected design element from the design databank; and
displaying information relating to at least one of the determined designs.

2. The method of claim 1, wherein in a data collection phase, the method further comprises:
selecting a design from the design database;
extracting data from the selected design;
converting the extracted data into a graph database format; and
storing the converted data in the design databank, the design databank being in the form of a graph database.

3. The method of claim 2, wherein extracting data from the selected design comprises:
creating an image file of the design selected from the design database; and
determining the design elements contained in selected design and an arrangement of the determined design elements in an image in the image file.

4. The method of claim 3, wherein extracting data from the selected design comprises serializing the image file into a string image file.

5. The method of claim 1, wherein displaying information relating to at least one of the determined designs comprises:
determining information relating to design elements that are arranged adjacent to the at least one selected design element in the determined designs that contain the at least one selected design element from the design databank; and
displaying the determined information relating to at least one design element.

6. The method of claim 5, further comprising determining and displaying, for the information relating to use of a design element as a design element adjacent to the at least one selected design element, statistics or a frequency in the determined designs or in a subgroup of the determined designs.

7. The method of claim 5, further comprising determining and displaying, for the information relating to use of a design element as a design element adjacent to the at least one selected design element, a recommended use as a design element adjacent to the selected design element.

8. The method of claim 6, wherein at least one predetermined group criterion defines a subgroup of the determined designs.

9. The method of claim 5, further comprising providing a user with an option of adopting at least one adjacent design element, or at least one adjacent design element and further design elements adjacent to the at least one adjacent design element from the determined designs of adjacent design elements for arrangement in the design in the design phase.

10. The method of claim 1, wherein the virtual model is a simulation model for simulating use of the component by at least one computer.

11. A computer system comprising:
at least one computer configured to generate a virtual model of a component using a computer-aided design (CAD) environment comprising a design database, the generation of the virtual model comprising:
store, using the design database, of designs;
provision, by the CAD environment, of predefined design elements from a design element collection, wherein at least some of the designs comprise predefined design elements, and wherein a design databank contains information from the design database relating to the designs; and
in a design phase:
selection of at least one design element of the predefined design elements,
determination of designs that contain the at least one selected design element from the design databank; and
display of information relating to at least one of the determined designs.

12. In a non-transitory computer-readable storage medium that stores instructions executable by a computer to generate a virtual model of a component using a computer-aided design (CAD) environment comprising a design database, the instructions comprising:
storing, using the design database, designs;
providing, by the CAD environment, predefined design elements from a design element collection, wherein at least some of the designs comprise predefined design elements, and wherein a design databank contains information from the design database relating to the designs; and
in a design phase:
selecting at least one design element of the predefined design elements,
determining designs that contain the at least one selected design element from the design databank; and
displaying information relating to at least one of the determined designs.

13. The non-transitory computer-readable storage medium of claim 12, wherein in a data collection phase, the instructions further comprise:
selecting a design from the design database;
extracting data from the selected design;
converting the extracted data into a graph database format; and
storing the converted data in the design databank, the design databank being in the form of a graph database.

14. The non-transitory computer-readable storage medium of claim 13, wherein extracting data from the selected design comprises:
creating an image file of the design selected from the design database; and
determining the design elements contained in selected design and an arrangement of the determined design elements in an image in the image file.

15. The non-transitory computer-readable storage medium of claim 14, wherein extracting data from the selected design comprises serializing the image file into a string image file.

16. The non-transitory computer-readable storage medium of claim 12, wherein displaying information relating to at least one of the determined designs comprises:
determining information relating to design elements that are arranged adjacent to the at least one selected design element in the determined designs that contain the at least one selected design element from the design databank; and
displaying the determined information relating to at least one design element.

17. The non-transitory computer-readable storage medium of claim 16, wherein the instructions further comprise determining and displaying, for the information relating to use of a design element as a design element adjacent to the at least one selected design element, statistics or a frequency in the determined designs or in a subgroup of the determined designs.

18. The non-transitory computer-readable storage medium of claim 16, wherein the instructions further comprise determining and displaying, for the information relating to use of a design element as a design element adjacent to the at least one selected design element, a recommended use as a design element adjacent to the selected design element.

19. The non-transitory computer-readable storage medium of claim 17, wherein at least one predetermined group criterion defines a subgroup of the determined designs.
